(19) United States
(12) Patent Application Publication
(10) Pub. No.: US 2002/0175720 A1
(43) Pub. Date: Nov. 28, 2002

(54) Circuit for adjusting operating voltage of a chip

(76) Inventors: Hung-Ju Huang, Taipei (TW); Hung-Ta Pai, Taichung Hsien (TW)

Correspondence Address: BIRCH STEWART KOLASCH & BIRCH, PO BOX 747, FALLS CHURCH, VA, 22040-0747, US

(21) Appl. No.: 09/949,920

(22) Filed: Sep. 12, 2001

(30) Foreign Application Priority Data
May 22, 2001 (TW) 90112219

(51) Int. Cl. H03B 19/00

(52) U.S. Cl. 327/113

(57) ABSTRACT

The present invention provides a circuit for adjusting operating frequency of a chip, and comprises an oscillator, a controlling circuit, and a voltage adjusting circuit. The oscillator is coupled to the chip for outputting a testing clock signal according to a voltage signal. The controlling circuit is coupled to the oscillator for comparing the testing clock signal and a predetermined clock frequency, then outputting a voltage controlling signal. The voltage adjusting circuit is coupled to the controlling circuit for adjusting the voltage value of the voltage signal according to the voltage controlling signal.

### BACKGROUND OF THE INVENTION

1. Field of the Invention

The present invention relates in general to a circuit for adjusting the operating voltage of a chip. In particular, the present invention relates to embedding a ring oscillator in a chip when the chip is produced. The frequency of the signal output by the ring oscillator is detected then compared with a predetermined value, which is equal to the anticipated output frequency of the oscillator. If the frequency of the signal output by the ring oscillator is lower than the predetermined value, the operating voltage of the chip is raised to make the signal output by the oscillator equal the predetermined value. Therefore, operating frequency of the chip will reach a targeted operating frequency.

2. Description of the Related Art

When an engineer designs a chip with sequential logic, the design must meet the timing requirements, which is the inverse of the operating frequency of the chip, under an operating voltage. If the chip is performance demanding, for example, a CPU or a graphics chip, the operating frequency is targeted as high as possible. Usually, more pipeline stages are required to reach higher operating frequencies. However, more pipeline stages implies that more gates are required in the chip. That is, the cost of chip is increased. The engineers simulate and verify their design based on the operating frequency under the operating voltage. On the other word, the timing of the design must be lower than the timing requirements under the operation voltage. To reduce the number of gates in the chip, the timing margin between the timing of the design and the timing requirements should be as small as possible. That is, the timing of the design should be as close to the timing requirements as possible. Usually, little deviation is allowed in the manufacturing of the chip.

After the design is complete, the chip is sent to a foundry for mass production. Due to manufacturing deviation, the targeted operating frequency for some versions of the chip may not be reached under the operating voltage. That is, the timing requirements is not met. To assure the performance of every version of the chip, the operating frequency should the same. Therefore, the chip that cannot meet the timing requirementss must be discarded, or its operating voltage must be increased to meet timing requirementss, since higher operating voltage means the desired voltage level can be reached more quickly.

However, because the manufacturing deviations of each manufacture step are not regular, it is hard to calculate the adjustment of the operating voltage to meet the timing of the chip.

### SUMMARY OF THE INVENTION

The object of the present invention is to provide a circuit for adjusting operating voltage of a chip to meet the timing requirements of the chip. This adjustment is based on the frequency of a ring oscillator, which is embedded in the chip. Because the ring oscillator and the chip are manufactured at the same time, if the deviation is generated in the process, the influence of the ring oscillator and the chip are the same. Therefore, the present invention adjusts operating voltage based on the frequency of a ring oscillator embedded in the chip to make chip's timing meet expectations.

To achieve the above-mentioned object, the present invention provides a circuit for adjusting operating frequency of a chip, and comprises an oscillator, a controlling circuit, and a voltage adjusting circuit. The oscillator is coupled to the chip for outputting a testing clock signal according to a voltage signal. The controlling circuit is coupled to the oscillator for comparing the testing clock signal and a predetermined clock frequency, then outputting a voltage controlling signal. The voltage adjusting circuit coupled to the controlling circuit for adjusting the voltage value of the voltage signal according to the voltage controlling signal.

### BRIEF DESCRIPTION OF THE DRAWINGS

The present invention will become more fully understood from the detailed description given hereinbelow and the accompanying drawings, given by way of illustration only and thus not intended to be limitative of the present invention.

FIG. 1 is an architecture block diagram according to the embodiment of the present invention.

FIG. 2 is an architecture diagram of the ring oscillator 13 according to the embodiment of the present invention.

FIG. 3 is a block diagram of the controlling circuit 14 according to the embodiment of the present invention.

FIG. 4 is a block diagram of the voltage adjusting circuit 15 according to the embodiment of the present invention.

FIG. 5 is an operation flow chart of the method for adjusting operating voltage of a chip according to the embodiment of the present invention.

FIG. 6 is an operation flow chart of the method for adjusting operating voltage if a chip operates from normal mode to power saving mode according to the embodiment of the present invention.

### DETAILED DESCRIPTION OF THE PREFERRED EMBODIMENT

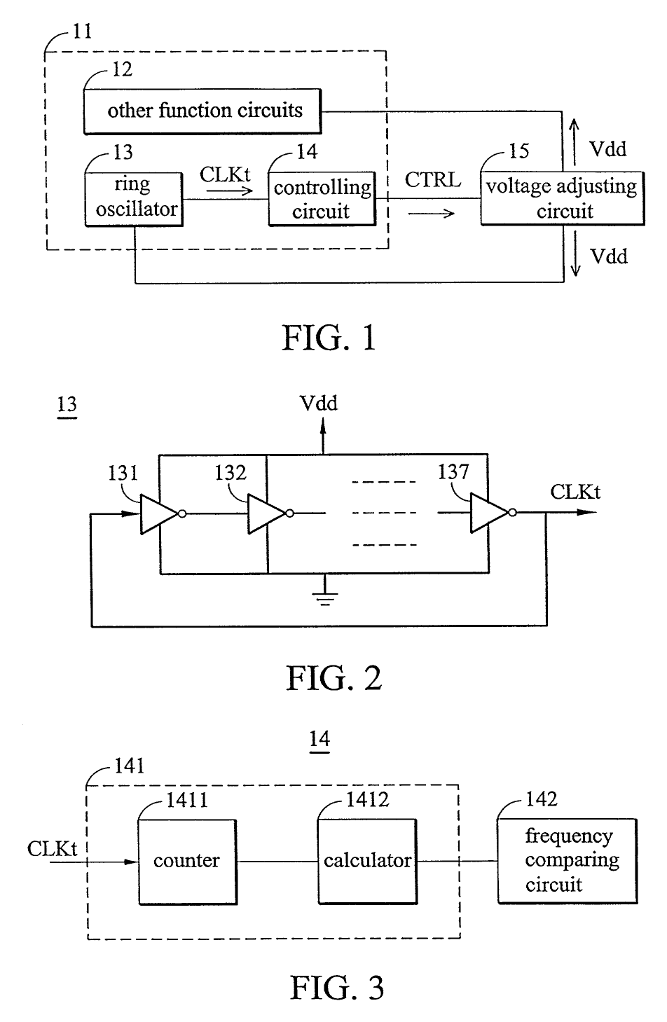

FIG. 1 is an architecture block diagram according to the embodiment of the present invention. Chip 11 comprises a ring oscillator 13, a controlling circuit 14 and other function circuits 12 and receives the voltage signal Vdd output by a voltage adjusting circuit 15.

The ring oscillator 13 is embedded in chip 11 and made up with chip 11 at the same time. The ring oscillator 13 outputs a testing clock signal CLKt according to a voltage signal Vdd. FIG. 2 is an architecture diagram of the ring oscillator 13 according to the embodiment of the present invention. The ring oscillator 13 is composed of an odd number of inverters 131˜137 (take seven as example in the present embodiment), each positive pole of the inverters is connected to the negative pole of the other one inverter (referring to FIG. 2). The default clock frequency of the ring oscillator 13 is designed according its design. Under the same operating voltage, if no deviation of the semiconductor manufacturing happens, the output clock frequency of the ring oscillator 13 will be the same for every version of the oscillator. As a result, manufacturing deviation of chip 11 with an embedded ring oscillator 13 can be detected by measuring the clock frequency of the ring oscillator 13.

The controlling circuit 14 is coupled to the ring oscillator 13 for comparing the testing clock signal CLKt and a predetermined clock frequency, then outputs a voltage controlling signal. The predetermined clock frequency is a perfection frequency output by the oscillator set by designers. FIG. 3 is a block diagram of the controlling circuit 14 according to the embodiment of the present invention. The controlling circuit 14 comprises a frequency calculating circuit 141 and a frequency comparing circuit 142.

The frequency calculating circuit 141 receives the testing clock signal CLKt and calculates the frequency of the testing clock signal. The testing clock signal serves as the clock of a counter 1411. The incremental amount of the counter 1411 is set as one. After a period of time T, the content N of the counter 1411 is read. Then, the time T and the content N are inputted to the calculator 1412, the calculator 1412 divides Nby T. Thus, the frequency of the testing clock signal CLKt is detected.

A frequency comparing circuit 142 is coupled to the frequency calculating circuit 141 to compare the testing clock signal and the predetermined clock frequency, and outputs the voltage controlling signal to control the voltage of the voltage signal. In normal mode, when the frequency of the testing clock signal CLKt is lower than the predetermined clock frequency, the voltage adjusting circuit 15 raises the operating voltage of the chip 11 according to the voltage controlling signal. At this time, the voltage signal output by the controlling circuit 14 is a voltage raising enable signal. In power saving mode, the operating frequency of the system is lowered to save power. Now the operating frequency of the system is set to X Hz, when the frequency of the testing clock signal CLKt is higher than X Hz, the voltage adjusting circuit 15 lowers the operating voltage of the chip 11 according to the voltage controlling signal. At this time, the voltage signal output by the controlling circuit 14 is a voltage lowering enable signal.

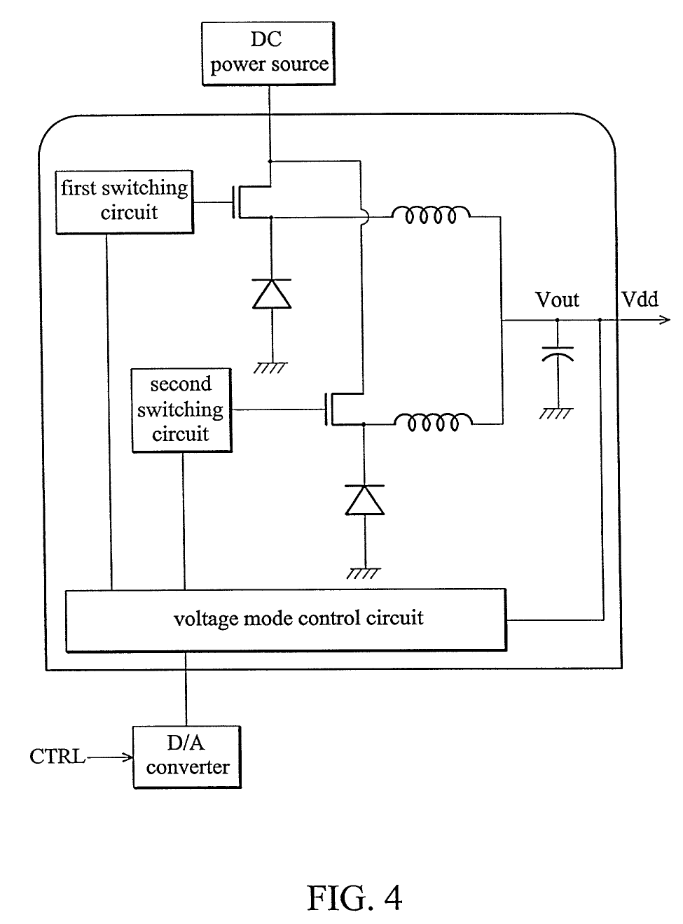

FIG. 4 is a block diagram of the voltage adjusting circuit 15 according to the embodiment of the present invention.

The detailed description of the voltage adjusting circuit 15 is disclosed in U.S. Pat. No. 5,959,441. The voltage signal Vdd is adjusted according to the voltage controlling signal CTRL. In the present embodiment, the voltage controlling signal CTRL is a digital signal. For example, if the voltage controlling signal CTRL is 0000 and the voltage signal Vdd is 1.5V, when the voltage controlling signal CTRL changes to 0001, the voltage signal Vdd will change to 1. 55V, and when the voltage controlling signal CTRL chenges to 0010, the voltage signal Vdd will change to 1.6V. Therefore, the voltage signal Vdd supplied to the chip 11 is adjusted depending on the the frequency of the testing clock signal CLKt output by the ring oscillator 13 to achieve the object of changing operating frequency by adjusting the operating voltage.

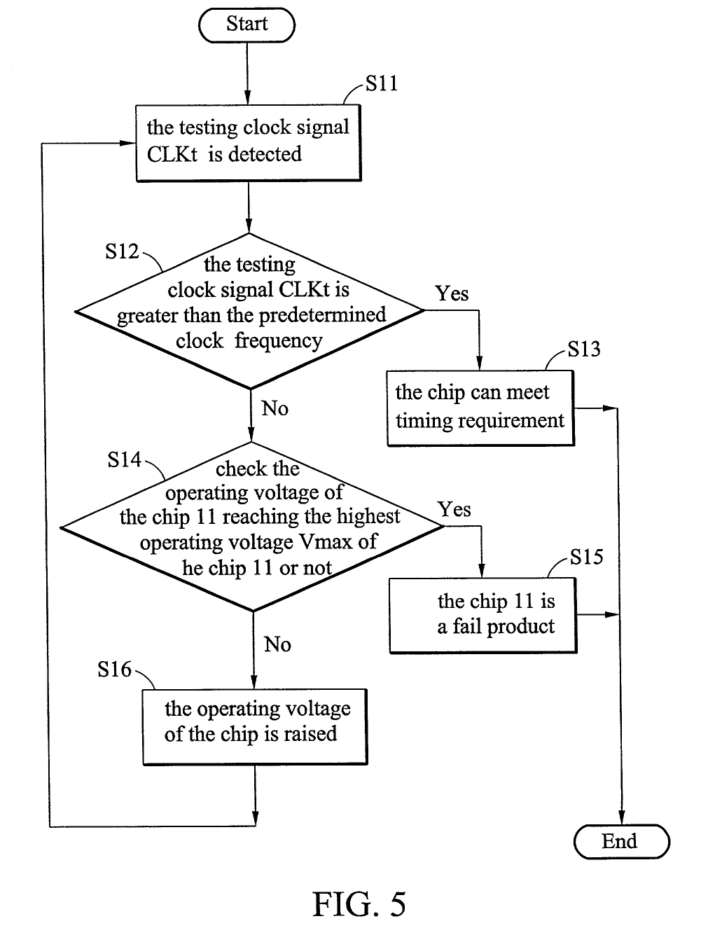

FIG. 5 is an operation flow chart of the method for adjusting operating voltage of a chip according to the embodiment of the present invention.

First, the testing clock signal CLKt output by the ring oscillator 13 is detected and calculated by counter 1411 and calculator 1412 (S11). Next, the frequency of the testing clock signal CLKt is compared with the predetermined clock frequency (S12). If the frequency of the testing clock signal CLKt is higher than or equal to the predetermined clock frequency, the chip can meet timing requirements (S13). If not, the operating voltage of the chip 11 reaching the highest operating voltage Vmax of the chip 11 is checked (S14). Here, the highest operating voltage Vmax is set by the designer. If yes, the chip 11 is a failed product (S15). If not, the operating voltage of the chip is raised by the voltage adjusting circuit 15 (S16), and the method returns to step 11.

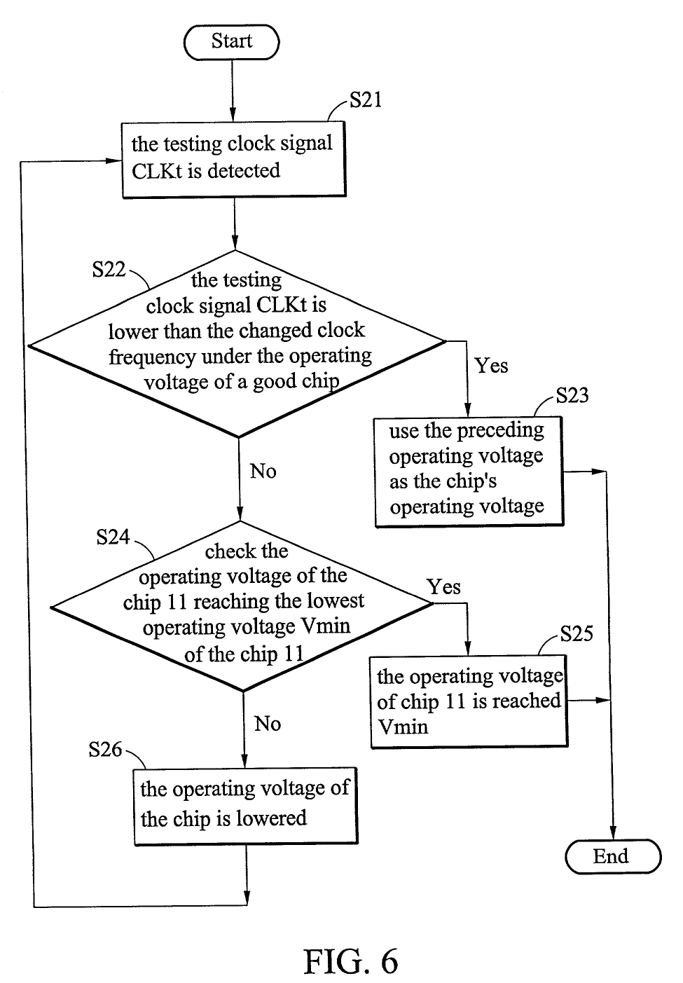

If the operation mode of chip 11 is changed from normal mode to power saving mode, the operating voltage is decreased to lower the operating frequency of the chip. FIG. 6 is an operation flow chart of the method for adjusting operating voltage if a chip operates from normal mode to power saving mode according to the embodiment of the present invention.

First, the testing clock signal CLKt output by the ring oscillator 23 is detected and calculated by counter 1411 and calculator 1412 (S21). Next, determines the frequency of the testing clock signal CLKt is lower than the changed clock frequency under the operating voltage of a good chip or not (S22). If yes, the preceding operating voltage is used as the chip's operating voltage (S23). If not, the operating voltage of the chip 11 reaching the lowest operating voltage Vmin of the chip 11 is checked (S24). Here, the lowest operating voltage Vmin is set by the designer. If yes, the operating voltage of chip 11 is reached Vmin (S25). If not, the operating voltage of the chip is lowered by the voltage adjusting circuit 15 (S26), and the method returns to step 21.

In addition, the desired output frequency of the ring oscillator 13 can be calculated based on the operating frequency in advance. For example, if the original operating frequency is 200 MHz and the output clock of the ring oscillator 13 is 60 MHz under the default operating voltage, for power saving mode, the new operating frequency may be reduced to 100 MHz. Then, the desired frequency of the ring oscillator 13 is 30 MHz.

The foregoing description of the preferred embodiments of this invention has been presented for purposes of illustration and description. Obvious modifications or variations are possible in light of the above teaching. The embodiments were chosen and described to provide the best illustration of the principles of this invention and its practical application to thereby enable those skilled in the art to utilize the invention in various embodiments and with various modifications as are suited to the particular use contemplated. All such modifications and variations are within the scope of the present invention as determined by the appended claims when interpreted in accordance with the breadth to which they are fairly, legally, and equitably entitled.

What is claimed is:

1. A circuit for adjusting operating frequency of a chip, comprising:
an oscillator coupled to the chip for outputting a testing clock signal according to a voltage signal;
a controlling circuit coupled to the oscillator for comparing the testing clock signal and a predetermined clock frequency, then outputting a voltage controlling signal; and
a voltage adjusting circuit coupled to the controlling circuit for adjusting the voltage value of the voltage signal according to the voltage controlling signal.

2. The circuit as claimed in claim 1, wherein the oscillator is embedded in the chip.

3. The circuit as claimed in claim 1, wherein the oscillator is composed of an odd number of inverters.

4. The circuit as claimed in claim 1, wherein the controlling circuit comprises:
a frequency calculating circuit for calculating the frequency of the testing clock signal; and
a frequency comparing circuit coupled to the frequency calculating circuit for comparing the testing clock signal and the predetermined clock frequency, and outputting the voltage controlling signal to raise the voltage of the voltage signal if the frequency of the testing clock signal is lower than the predetermined clock frequency.

5. The circuit as claimed in claim 1, wherein the predetermined clock frequency is a perfection frequency output by the oscillator and set by designers.

6. The circuit as claimed in claim 1, wherein the voltage controlling signal output by the controlling circuit is a voltage raising enable signal if the frequency of the testing clock signal is lower than the predetermined clock frequency, and the voltage adjusting circuit raises the voltage of the voltage signal according to the voltage raising enable signal.

7. The circuit as claimed in claim 1, wherein the voltage controlling signal output by the controlling circuit is a voltage lowering enable signal if the frequency of the testing clock signal is higher than the predetermined clock frequency, and the voltage adjusting circuit lowers the voltage of the voltage signal according to the voltage lowering enable signal.

8. A method for adjusting operating frequency of a chip, comprising the following steps:
providing a chip having an oscillator;
detecting the output frequency of the oscillator; and
adjusting operating voltage of the chip according to the output frequency.

9. The method as claimed in claim 8, further comprising the following step:
raising the operating voltage if the output of the oscillator is lower than a first frequency, wherein the chip operates in normal mode.

10. The method as claimed in claim 9, wherein the first frequency is a frequency output by the oscillator in perfection and in normal mode.

11. The method as claimed in claim 8, further comprising the following step:
lowering the operating voltage if the output of the oscillator is higher than a second frequency, wherein the chip operates in power saving mode.

12. The method as claimed in claim 11, wherein the second frequency is a perfection frequency output by the oscillator set by designers.
